(19) United States
(12) Patent Application Publication
(10) Pub. No.: US 2022/0285260 A1
(43) Pub. Date: Sep. 8, 2022

(54) METALLIZATION STRUCTURE OF DISTRIBUTED GATE DRIVE FOR IMPROVING MONOLITHIC FET ROBUSTNESS

(71) Applicants: Jialun Du, Powell, OH (US); Jiwei Fan, Cary, NC (US); Guifang Wen, Shenzhen (CN)

(72) Inventors: Jialun Du, Powell, OH (US); Jiwei Fan, Cary, NC (US); Guifang Wen, Shenzhen (CN)

(21) Appl. No.: 17/444,304

(22) Filed: Aug. 3, 2021

Related U.S. Application Data
(60) Provisional application No. 63/200,394, filed on Mar. 4, 2021.

(51) Int. Cl. H01L 23/528

(52) U.S. Cl. CPC H01L 23/528; H01L 23/53214

(57) ABSTRACT

A metallization structure of distributed gate drive enabling the switching behavior of different MOSFET arrays and fingers to be more unified while maintaining the same Rdson and Qg performance. This balances the transient current between MOSFET arrays and fingers during switching, allowing the device to operate at a much higher current.

### CROSS-REFERENCE TO RELATED APPLICATION

This application claims the benefit of priority of U.S. provisional application No. 63/200,394, filed 4 Mar. 2021, the contents of which are herein incorporated by reference.

### BACKGROUND OF THE INVENTION

The present invention relates to the electronic arts and, more particularly, a new metallization structure of distributed gate drive for improving monolithic FET robustness.

In monolithic power-stage and point-of-load products, switching synchronicity of power MOSFETs plays an important role in product robustness. Power MOSFET often include multiple arrays and fingers, and is usually very large, relatively speaking, in size. When different areas of the Power MOSFET are switching asynchronously, effectuating unbalanced delay between different regions of MOSFET, a small portion of the MOSFET would conduct a majority of the switching current, which can be 2 to 3 times the maximum allowable current that the device can handle. This results in local overvoltage and overcurrent stress and overheating on certain MOSFET locations, not only degrading FET long-term robustness and reliability (i.e., preventing the device from operating at higher current and degrading thermal performance) but also causing, in extreme conditions, instantaneous FET failures.

Accordingly, today's products can easily fail at heavy load current, and their thermal performance and power efficiency are suboptimal.

As can be seen, there is a need for a unique metallization structure of distributed gate drive enabling the switching behavior of different MOSFET arrays and fingers to be more unified while maintaining the same Rdson and Qg performance. This balances the transient current between MOSFET arrays and fingers during switching, allowing the device to operate at a much higher current.

By implementing the new metallization structure of the power MOSFET of the present invention in driver systems, the propagation delay between different sections of power MOSFET were very well balanced, allowing different sections of MOSFET to switch synchronously. In this way, the switching current would be evenly distributed across the whole power MOSFET. This resolves the local overvoltage and overcurrent stress issue, removes local hotspot and improves MOSFET long-term robustness and reliability significantly.

When comparing against state-of-art products from competitors with the same die size, the present invention doubles the safe operating DC current. When operating at the same heavy load current, the product with the present invention is 20 degrees Celsius lower in temperature. Furthermore, the instantaneous in-field device failures were observed much less frequently after implementing the present invention.

### SUMMARY OF THE INVENTION

In one aspect of the present invention, a semiconductor device includes the following: a semiconductor die formed with a plurality of transistor arrays forming a monolithic power stage or point-of-load device; a routing metallic layer electrically coupled to each gate of each transistor of said plurality of transistor arrays; and a plurality of gate drivers positioned along a periphery of said semiconductor die and electrically coupled to each gate of each transistor of said plurality of transistor arrays through said routing metallic layer.

In another aspect of the present invention, above-mentioned semiconductor device further includes an input signal metallization network positioned along a periphery of said plurality of gate drivers, wherein the input signal metallization network and the routing metallic layer are in parallel, wherein the input signal metallization network and the routing metallic layer are low impedance metals, wherein the input signal metallization network and the routing metallic layer are aluminum metals; further including a first metallic layer for each transistor array of the plurality of transistor arrays, the first metallic layer is subjacent the routing metallic layer, wherein the first metallic layer comprise a source connection and a drain connection for each transistor in said transistor array, wherein the first metallic layer is staggered in a first direction; further including a second metallic layer for each transistor array of the plurality of transistor arrays is in line the routing metallic layer, wherein the second metallic layer provide a source and a drain connection for each transistor in said transistor array, wherein the second metallic layer is staggered in a second direction; further including a third metallic layer superjacent the routing metallic layer; further including a first via path between the first metallic layer and the second metallic layer; further including a third via path between the third metallic layer and the second metallic layer, wherein the semiconductor device is configured in such a way that during an on state, a current via the input signal metallization network flows from the plurality of gate drivers through the routing metallic layer to each transistor array of the plurality of transistor arrays in the first direction; further including a plurality of fingers provided by each transistor array, wherein each finger of each plurality of fingers are configured to equally share said current, wherein the routing metallic layer connects to each gate of through the first via path and the first metallic layer.

These and other features, aspects and advantages of the present invention will become better understood with reference to the following drawings, description and claims.

### BRIEF DESCRIPTION OF THE DRAWINGS

FIG. 1 is a schematic view of an exemplary embodiment of the present invention; and

FIG. 2 is a layout view of an exemplary embodiment of the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, an embodiment of the present invention provides a metallization structure of distributed gate drive enabling the switching behavior of different MOSFET arrays and fingers to be more unified while maintaining the same Rdson and Qg performance. This balances the transient current between MOSFET arrays and fingers during switching, allowing the device to operate at a much higher current.

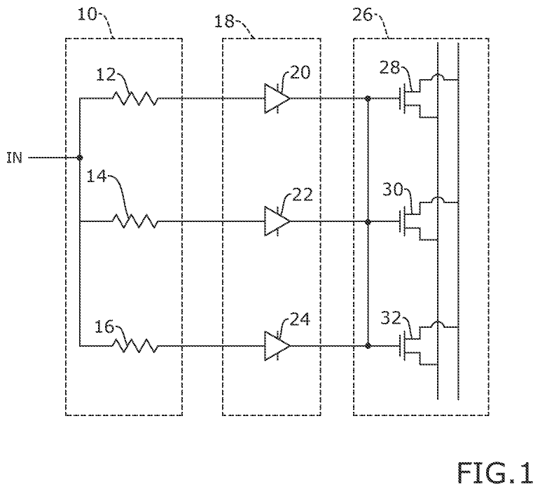

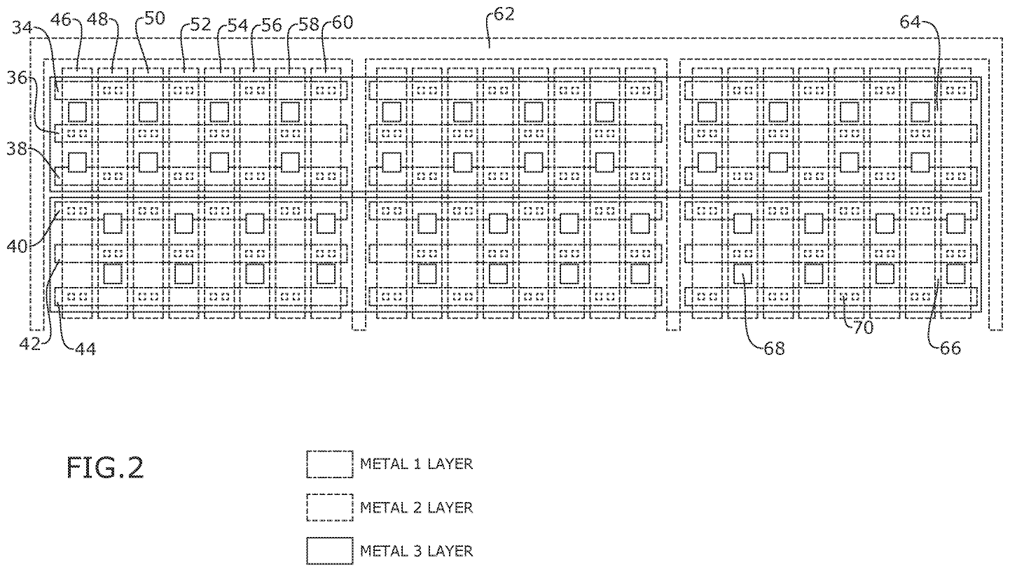

Referring now to FIGS. 1 and 2, the present invention may include the following systemic components:
10. Input signal metallization network
12. Input metal resistance for first driver array
14. Input metal resistance for second driver array
16. Input metal resistance for third driver array
18. Distributed gate driver system
20. Gate driver for first MOSFET array
22. Gate driver for second MOSFET array
24. Gate driver for third MOSFET array
26. Distributed MOSFET arrays
28. First MOSFET array
30. Second MOSFET array
32. Third MOSFET array
34. Metal1 for MOSFET source connection
36. Metal1 for MOSFET drain connection
38. Metal1 for MOSFET source connection
40. Metal1 for MOSFET drain connection
42. Metal1 for MOSFET source connection
44. Metal1 for MOSFET drain connection
46. Metal2 for MOSFET drain connection
48. Metal2 for MOSFET source connection
50. Metal2 for MOSFET drain connection
52. Metal2 for MOSFET source connection
54. Metal2 for MOSFET drain connection
56. Metal2 for MOSFET source connection
58. Metal2 for MOSFET drain connection
60. Metal2 for MOSFET source connection
62. Metal2 for MOSFET gate connection
64. Metal3 for MOSFET drain connection
66. Metal3 for MOSFET source connection
68. VIA23 (The VIA provide a conductive path for passing an electrical signal from one circuit layer to another via a plated hole wall or equivalent): VIA23 is a conductive path between layer 2 and layer 3.
70. VIA12

Referring to FIG. 1, FIG. 1 shows the structure of the distributed gate drive for monolithic power stage and point-of-load products. The input signal (IN) is connected to the gate driver (20) via its metal resistor (12). The gate driver (20) is connected to the gate of the first MOSFET array (28). The input signal (IN) is connected to the gate driver (22) via its metal resistor (14). The gate driver (22) is connected to the gate of the second MOSFET array (30). The input signal (IN) is connected to the gate driver (24) via its metal resistor (16). The gate driver (24) is connected to the gate of the third MOSFET array (32). The gates of adjacent MOSFET arrays (28) (30) (32) are electrically connected.

FIG. 1 only shows three subroutines of the distributed gate driver for illustration purpose. This subroutine of input metal resistor connected with gate driver connected with its corresponding MOSFET array is scalable. The input metal resistors (12), (14) and (16) forms the input signal metallization system (10). The gate drivers (20), (22) and (24) forms the distributed gate driver system (18). The distributed MOSFET (26) includes of MOSFET arrays (28), (30) and (32). The metallization of the distributed MOSFET (26) is illustrated in FIG. 2 in more detail.

Referring now to FIG. 2, FIG. 2 shows the metallization of the distributed MOSFET in layout view. The diffusion and poly layers of the MOSFET were not shown in the drawing for simplicity. METAL1 layer (34), (38) and (42) are MOSFET source connections and are connected to METAL2 layer (48), (52), (56) and (60) through VIA12 (70). METAL1 layer (36), (40) and (44) are MOSFET drain connections and are connected to METAL2 layer (46), (50), (54) and (58) through VIA12 (70). The source and drain of the other two MOSFET arrays on the right follow the same way of connection. METAL2 layer (62) is used as the gate routing metal of the three MOSFET arrays. The METAL2 layer connects to the actual gate of MOSFET through the layers of VIA12, METAL1, CONTACT and POLY, from top to bottom, which has been omitted from the drawing for simplicity. MOSFET drain METAL2 layers (46), (50), (54), (58) and the METAL2 drain connections of the other two MOSFET arrays on the right are connected to METAL3 layer (64) through VIA23 (68). MOSFET source METAL2 layers (48), (52), (56), (60) and the METAL2 source connections of the other two MOSFET arrays on the right are connected to METAL3 layer (66) through VIA23 (68). The METAL3 source and drain connections are connected to the device package through copper pillar or bond wire, which has been omitted from the drawing for simplicity.

In operation, the input signal IN is a digital signal that controls the MOSFET on and off. When the IN signal is high, all the MOSFET arrays and fingers should turn on. When the IN signal is low, all the MOSFET arrays and fingers should turn off. The input signal IN may be distributed into the gate drivers (18) through the metal resistor network (10). All the metal resistors (12), (14), (16), etc., should be matched so that the input signal IN arrives at the inputs of each gate driver simultaneously. All the metal resistors (12), (14) and (16) should use low impedance metal routing or by stacking several layers of metals so that the mismatch between each signal line can be minimized. All the gate drivers (20), (22) and (24) should be identical. Inside each gate driver, the input signal is buffered up to have sufficient output driving capability. When the input of the gate driver (20) goes high, the output of the driver will source current into the gate of the MOSFET (28), charging the Cgs of the MOSFET. When the VGS of the MOSFET is charged up above its threshold, the MOSFET turns on. The metal routing from the output of gate driver (20) to the gate of MOSFET (28) needs to be in low impedance metal or by stacking several layers of metals so that all the MOSFET fingers can achieve simultaneous switching. The same control mechanism applies for gate driver (22) to MOSFET array (30) and gate driver (24) to MOSFET array (32). The gates of all the MOSFET arrays (26) are also connected in low impedance metal to help balance the gate charge. The connection can be made in low impedance metal or by stacking several layers of metals with slightly higher impedance.

The layout of three MOSFET arrays' metallization is illustrated in FIG. 2. For each MOSFET array, the MOSFET source and drain connections are the horizontal METAL1 bars (34)˜(44) and are staggered in vertical direction. The METAL1 source and drain connections are brought up to METAL2 bars (46)˜(60) through VIA12 and are staggered in horizontal direction. The METAL2 source and drain connections of each MOSFET array are brought up to METAL3 (64)˜(66) through VIA23 (68). The METAL3 is often the top metal that is connected to the device package through copper pillar or bond wire. The MOSFET gate is routed in low impedance METAL2 layer (62). The gates of adjacent MOSFET arrays are connected using METAL2 as well. During MOSFET turn on, current will flow from the gate driver through the gate metallization network (62) to each individual MOSFET array and its MOSFET fingers in vertical direction. Since the gate (62) is routed in very low impedance metal, the propagation delay from the driver to each MOSFET array and its finger is balanced very well. This would allow all the MOSFET fingers to equally share the transient current during MOSFET turn on. However, if the gate (62) is not routed in low impedance metal, the MOSFET fingers at the top would turn on earlier than the fingers at the bottom. Thus, the MOSFET fingers at the top would take most of the transient current. When comparing the current that the top fingers conduct with and without the low impedance gate metal routing, the current without low impedance routing can be 2 to 3 times higher than the one with low impedance routing. Similarly, when the MOSFET turns off, the fingers at the bottom would turn off much later than the fingers at the top, which would make the bottom fingers conduct more current than the top fingers. The current unbalance of different MOSFET areas causes overstress and overheat on certain areas of the MOSFET, which is the root cause to a lot of the MOSFET device failures. By providing the novel architecture embodied in the present invention the gate metallization system, the local overstress or overheat problem can be fundamentally resolved, improving FET long-term robustness and reliability significantly.

FIG. 1 and FIG. 2 gives an illustration of the distributed gate drive architecture and its layout metallization system. One can design the distributed gate drive for monolithic power stage or point-of-load by simply following the descriptions above and scale the distributed gate drive as needed.

In today's power stage or point-of-load products, the metal stack often come in two aluminum metals plus one copper metal, or three aluminum metals plus one copper metal. The input signal IN metallization network (10) and the MOSFET gate metal routing (62) is required to be routed in low impedance metal. For two aluminum metals plus one copper metal stack, the metal routing for these two items can be the two aluminum metals in parallel. Furthermore, the metal width should be as thick as possible to further decrease the metal resistance. For three aluminum metals plus one copper metal stack, the top aluminum metal often comes with low square-ohm resistance which can be directly used as the routing metal for the input signal IN metallization network (10) and the MOSFET gate (62).

The metal resistance of (12), (14) and (16) should be matched as much as possible. The individual driver blocks (20), (22) and (24) should be designed to be identical. The driving capability of the drivers should be properly designed to balance the trade-offs between ringing and power loss. The MOSFET gate metal routing (62) may be shared between adjacent MOSFET arrays. Following the metallization structure for MOSFET source and drain illustrated in FIG. 2 is recommended to improve the Rdson of the MOSFET.

Low impedance routing for input signal IN metallization network (10) is required. Low impedance routing for MOSFET gate (62) is required. Sharing of metal routing between gates of adjacent MOSFET arrays is required. Enclose of low impedance MOSFET gate routing for the entire MOSFET area is required.

Matching of the input metal resistance (12), (14), (16) is optional.

The MOSFET source and drain metallization structure illustrated in FIG. 2 is optional. One can decide the best source and drain metallization structure to achieve the best Rdson performance of the device based on specific manufacturing process.

The architecture of the distributed gate drive can be slightly altered. FIG. 1 shows a single driver driving the MOSFET array from one side. Alternatively, a plurality of drivers can drive the MOSFET from both sides to perform the same function.

The MOSFET source and drain layout metallization system can change and may not affect the present invention's functionality. Systemic components can be altered, including the numbers of metal layers used for source and drain routing, the length and width of each metal layer, the VIA placement and number of VIAs.

A designer would need to re-architecture the monolithic MOSFET gate drive design by following the steps described based on FIG. 1. Then the designer would need to layout the distributed gate drive according to FIG. 2 by following the steps described above. In order to make the invention functional, the designer would need to follow at least the previous elements/steps that have been identified as required. It is strongly recommended that the designer follows the optional elements/steps as well to achieve the best performance of the present invention. Finally, the designer would need to find a trusted semiconductor manufacturer to fabricate the product.

It should be understood, of course, that the foregoing relates to exemplary embodiments of the invention and that modifications may be made without departing from the spirit and scope of the invention as set forth in the following claims.

What is claimed is:

1. A semiconductor device, comprising:
a semiconductor die formed with a plurality of transistor arrays forming a monolithic power stage or point-of-load device;
a routing metallic layer electrically coupled to each gate of each transistor of said plurality of transistor arrays; and
a plurality of gate drivers positioned along a periphery of said semiconductor die and electrically coupled to each gate of each transistor of said plurality of transistor arrays through said routing metallic layer.

2. The semiconductor device of claim 1, further comprising an input signal metallization network positioned along a periphery of said plurality of gate drivers.

3. The semiconductor device of claim 2, wherein the input signal metallization network and the routing metallic layer are in parallel.

4. The semiconductor device of claim 3, wherein the input signal metallization network and the routing metallic layer are low impedance metals.

5. The semiconductor device of claim 4, wherein the input signal metallization network and the routing metallic layer are aluminum metals.

6. The semiconductor device of claim 5, further comprising a first metallic layer for each transistor array of the plurality of transistor arrays, the first metallic layer is subjacent the routing metallic layer, wherein the first metallic layer comprise a source connection and a drain connection for each transistor in said transistor array.

7. The semiconductor device of claim 6, wherein the first metallic layer is staggered in a first direction.

8. The semiconductor device of claim 7, further comprising a second metallic layer for each transistor array of the plurality of transistor arrays is in line the routing metallic layer, wherein the second metallic layer provide a source and a drain connection for each transistor in said transistor array.

9. The semiconductor device of claim 8, wherein the second metallic layer is staggered in a second direction.

10. The semiconductor device of claim 9, further comprising a third metallic layer superjacent the routing metallic layer.

11. The semiconductor device of claim 10, further comprising a first via path between the first metallic layer and the second metallic layer.

12. The semiconductor device of claim 11, further comprising a second via path between the third metallic layer and the second metallic layer.

13. The semiconductor device of claim 12, wherein the semiconductor device is configured in such a way that during an on state, a current via the input signal metallization network flows from the plurality of gate drivers through the routing metallic layer to each transistor array of the plurality of transistor arrays in the first direction.

14. The semiconductor device of claim 13, further comprising a plurality of fingers provided by each transistor array, wherein each finger of each plurality of fingers are configured to equally share said current.

15. The semiconductor device of claim 14, wherein the routing metallic layer connects to each gate of through the first via path and the first metallic layer.
